(19) United States
(12) Patent Application Publication
(10) Pub. No.: US 2026/0018216 A1
(43) Pub. Date: Jan. 15, 2026

(54) MEMORY READS USING PREDICITVE READ OFFSETS

(71) Applicant: Micron Technology, Inc., Boise, ID (US)

(72) Inventors: Arghyadeep Bandyopadhyay, Haldia (IN); Amiya Banerjee, Thanisandra (IN)

(21) Appl. No.: 19/259,526

(22) Filed: Jul. 3, 2025

Related U.S. Application Data
(60) Provisional application No. 63/668,986, filed on Jul. 9, 2024.

(51) Int. Cl. G11C 16/26; G11C 16/08; G11C 16/34

(52) U.S. Cl. CPC G11C 16/26; G11C 16/08; G11C 16/3495

(57) ABSTRACT

The present disclosure configures a memory sub-system controller to perform reads in a memory sub-system using predictive read offsets. The controller receives a request to read a word line group (WLG) of a set of memory components. The controller stores a table that associates a first read level offset with a first region of the WLG and a second read level offset with a second region of the WLG. The controller reads a first set of data stored in the first region of the WLG using the first read level offset stored in the table and reads a second set of data stored in the second region of the WLG using the second read level offset stored in the table.

### PRIORITY APPLICATION

This application claims the benefit of priority to U.S. Provisional Application Ser. No. 63/668,986, filed Jul. 9, 2024, which is incorporated herein by reference in its entirety.

### TECHNICAL FIELD

This disclosure relates generally to memory sub-systems and, more specifically, to providing adaptive media management for memory components, such as memory dies.

### BACKGROUND

A memory sub-system can be a storage system, such as a solid-state drive (SSD), and can include one or more memory components that store data. The memory components can be, for example, non-volatile memory components and volatile memory components. In general, a host system can utilize a memory sub-system to store data on the memory components and to retrieve data from the memory components.

### BRIEF DESCRIPTION OF THE DRAWINGS

The present disclosure will be understood more fully from the detailed description given below and from the accompanying drawings of various embodiments of the disclosure.

FIG. 1 is a block diagram illustrating an example computing environment including a memory sub-system, in accordance with some examples.

FIG. 2 is a block diagram of an example media operations manager, in accordance with some examples.

FIG. 3 is a block diagram of an example of a read level computation component in the memory sub-system, in accordance with some examples.

FIGS. 4 and 5 are flow diagrams of example methods to selectively perform coarse and fine read level offset computations, in accordance with some examples.

FIG. 6 is a block diagram illustrating a diagrammatic representation of a machine in the form of a computer system within which a set of instructions can be executed for causing the machine to perform any one or more of the methodologies discussed herein, in accordance with some examples.

### DETAILED DESCRIPTION

The present disclosure configures a system component, such as a memory sub-system controller, to selectively perform coarse and fine read level offset computations when reading data from one or more components in a memory sub-system. The memory sub-system controller can divide a portion (e.g., a word line group [WLG]) of the memory components into multiple regions. The memory sub-system controller can then compute respective read level offsets for each WL in each region using coarse and fine read level computations of a valley track process and store the offsets in a table. The memory sub-system controller can then read data from each region in the WLG according to the previously computed read level offsets stored in the table without recomputing the course and fine read level offsets. The memory sub-system controller can continue reading the data from the regions in this manner until a read recovery flow trigger rate transgresses a threshold. At that point, additional regions can be generated based on a read bit error rate (RBER) of WLs in the region and new read level offsets for the additional regions can be computed and added to the table. This avoids performing such coarse and fine read level offset computations each time data is read from the memory components, such as quad level cell (QLC) blocks of the memory components which reduces power consumption and latency. This improves the overall efficiency of operating the memory sub-system.

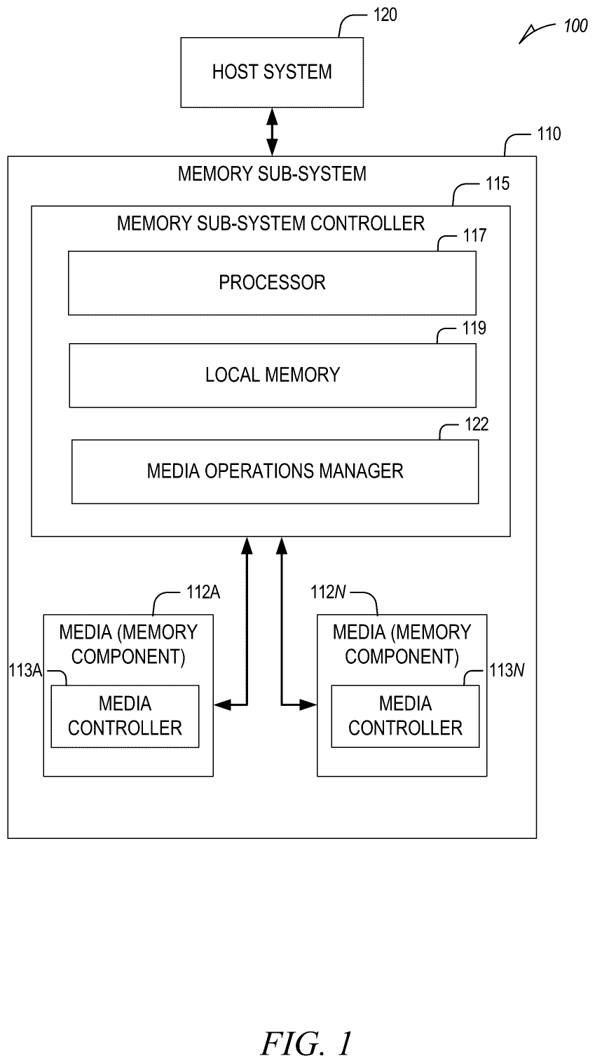

A memory sub-system can be a storage device, a memory module, or a hybrid of a storage device and memory module. Examples of storage devices and memory modules are described below in conjunction with FIG. 1. In general, a host system can utilize a memory sub-system that includes one or more memory components, such as memory devices (e.g., memory dies or planes across multiple memory dies) that store data. The host system can send access requests (e.g., write command, read command) to the memory sub-system, such as to store data at the memory sub-system and to read data from the memory sub-system. The data (or set of data) specified by the host is hereinafter referred to as “host data,” “application data,” or “user data”.

The memory sub-system can initiate media management operations, such as a write operation, on host data that is stored on a memory device. In some examples, firmware of the memory sub-system may re-write previously written host data from a location on a memory device to a new location as part of garbage collection management operations. The data that is re-written, for example as initiated by the firmware, is hereinafter referred to as “garbage collection data”. “User data” can include host data and garbage collection data. “System data” hereinafter refers to data that is created and/or maintained by the memory sub-system for performing operations in response to host requests and for media management. Examples of system data include, and are not limited to, system tables (e.g., logical-to-physical address mapping table), data from logging, scratch pad data, etc.

Many different media management operations can be performed on the memory device. For example, the media management operations can include different scan rates, different scan frequencies, different wear leveling, different read disturb management, different near miss error correction code (ECC), and/or different dynamic data refresh. Wear leveling ensures that all blocks in a memory component approach their defined erase-cycle budget at the same time, rather than some blocks approaching it earlier. Read disturb management counts all of the read operations to the memory component. If a certain threshold is reached, the surrounding regions are refreshed. Near-miss ECC refreshes all data read by the application that exceeds a configured threshold of errors. Dynamic data-refresh scan reads all data and identifies the error status of all blocks as a background operation. If a certain threshold of errors per block or ECC unit is exceeded in this scan-read, a refresh operation is triggered.

A memory device can be a non-volatile memory device. A non-volatile memory device is a package of one or more dice (or dies). Each die can be comprised of one or more planes. For some types of non-volatile memory devices (e.g., NAND devices), each plane is comprised of a set of physical blocks. For some memory devices, blocks are the smallest area that can be erased. Each block is comprised of a set of pages. Each page is comprised of a set of memory cells, which store bits of data. The memory devices can be raw memory devices (e.g., NAND), which are managed externally, for example, by an external controller. The memory devices can be managed memory devices (e.g., managed NAND), which is a raw memory device combined with a local embedded controller for memory management within the same memory device package.

There are challenges in efficiently managing or performing media management operations on typical memory devices. In the context of NAND flash memory, particularly with QLC technology, the challenge of maintaining high read performance while ensuring data integrity is significant. QLC technology, which stores four bits per cell, inherently exhibits a lower Read Window Budget (RWB) compared to Triple-Level Cell (TLC) or other types of word lines (WLs). This lower RWB makes it important to precisely adjust read offsets to minimize read errors and reduce the frequency of triggering recovery flows. To address this, a combination of coarse (Digital CFByte) and fine (pARC) read level offset computation and/or calibration algorithms is employed. These algorithms can be used for determining the shift in read level due to charge loss among other issues, which can impact the reliability of data retrieval. However, the use of Digital CFByte (DCFByte) and PARC calibration introduces additional latency into the read process. For instance, the typical page read time (tR) without any calibration can be performed in 74 microseconds (μs) but when DCFByte and pARC are applied, this read time increases to approximately 89 μs, adding about 15-16 us of overhead. This latency is primarily due to the time used to compute both coarse and fine read level offsets each time data is read from a QLC block.

This overhead not only impacts the efficiency of read operations but also consumes additional computational r resources. Each read operation needs recalibration to adjust for potential charge loss, leading to increased processing time and energy consumption. This is particularly problematic in read-intensive workloads, where the frequency of read operations can exacerbate these delays and resource usage, ultimately affecting the overall system performance.

The present disclosure addresses the above and other deficiencies by providing a memory controller that can selectively perform coarse and fine read level offset computations when reading data from one or more components in a memory sub-system. The memory sub-system controller predicts the read offsets instead of recalibrating them with each read operation. By persisting these read offsets and applying them through read offset prefix cycles, the disclosed techniques reduce read latencies. In this way, the disclosed techniques maintain the balance between performance and reliability, reducing the latency introduced by DCFByte and pARC without substantially increasing the risk of read errors or recovery flow triggers. This improves the overall efficiency of operating the memory sub-system.

In some examples, the memory controller receives a request to read a WLG of the set of memory components. The controller stores a table that associates a first read level offset with a first region of the WLG and a second read level offset with a second region of the WLG. The controller reads a first set of data stored in the first region of the WLG using the first read level offset stored in the table and reads a second set of data stored in the second region of the WLG using the second read level offset stored in the table.

The memory sub-system can include a three-dimensional (3D) NAND memory. In some cases, the first set of data and the second set of data are read from the set of memory components without computing coarse and fine read level offsets using a valley track process. The controller can determine that a quantity of regions in the WLG transgresses a maximum number of regions. The controller, in response to determining that the quantity of regions in the WLG transgresses the maximum number of regions, reads data stored in the WLG using coarse and fine read level offsets computed using a valley track process.

In some examples, the controller detects that a QLC block has been written. In response, the controller selects one or more WLs (e.g., a selected set of WLs) from each WLG and performs a set of read operations on the selected WL(s) using coarse and fine read level offsets computed using a valley track process. The selected WL(s) can be selected randomly. The selected WL(s) can correspond to one or more WLs having reliability values that fail to transgress a reliability threshold.

The controller performs the set of read operations on all sub-blocks of the QLC block. In some cases, the controller performs the set of read operations on a portion of sub-blocks of the QLC block that are associated with reliability values that fail to transgress a reliability threshold. In some examples, the controller computes a plurality of coarse and fine read level offsets for the portion of the sub-blocks and computes a mean offset based on the plurality of coarse and fine read level offsets. The controller stores the mean offset in the table in association with the selected set of WLs. In some cases, the controller performs subsequent reads on the selected set of WLs using the mean offset stored in the table without computing coarse and fine read level offsets using the valley track process.

The controller can compute a read recovery flow trigger rate for each WL in the WLG. In some cases, the controller determines that the read recovery flow trigger rate for the WLG transgresses a WLG threshold. In such cases, the controller, in response to determining that the read recovery flow trigger rate for the WLG transgresses the WLG threshold, selects a portion of WLs in the WLG; and performing read operations on the selected portion of WLs. In some examples, the controller computes a read bit error rate (RBER) for the selected portion of WLs in response to performing the read operations. The controller identifies an individual WL in the selected portion of WLs having a larger RBER than the RBER of other WLs in the selected portion of WLs and divides the WLG into a plurality of regions including the first and second regions based on the identified individual WL.

The controller identifies an individual WL in the WLG for which the read recovery flow trigger rate transgresses a WL threshold. The controller divides the WLG into a plurality of regions including the first and second regions based on the identified individual WL. In some cases, the WLG threshold and the WL threshold are computed based on a read throughput associated with the recovery flow trigger rate. In some cases, the controller determines how many regions are in the WLG in response to dividing the WLG into the plurality of regions. The controller, in response to determining that a quantity of regions in the WLG transgresses a threshold, performs subsequent reads on the WLG using the valley track process. In some examples, the controller, in response to determining that the quantity of regions in the WLG fails to transgress the threshold, performs subsequent reads on the WLG according to the read level offsets stored in the table.

Though various examples are described herein as being implemented with respect to a memory sub-system (e.g., a controller of the memory sub-system), some or all of the portions of an example can be implemented with respect to a host system, such as a software application or an operating system of the host system.

FIG. 1 illustrates an example computing environment 100 including a memory sub-system 110, in accordance with some examples. The memory sub-system 110 can include media, such as memory components 112A to 112N (also hereinafter referred to as “memory devices”). The memory components 112A to 112N can be volatile memory devices, non-volatile memory devices, or a combination of such. The memory components 112A to 112N can be implemented by individual dies, such that a first memory component 112A can be implemented by a first memory die (or a first collection of memory dies) and a second memory component 112N can be implemented by a second memory die (or a second collection of memory dies). Each memory die can include a plurality of planes in which data can be stored or programmed.

In some examples, the first memory component 112A (including a WL, a WLG, a block, or page of the first memory component 112A), or group of memory components including the first memory component 112A can be associated with a first reliability (capability) grade, value, measure, or lifetime PEC. The terms “reliability grade,” “value” and “measure” are used interchangeably throughout and can have the same meaning. The second memory component 112N (a WL, a WLG, a block, or page of the second memory component 112N) or group of memory components including the second memory component 112N can be associated with a second reliability (capability) grade, value, measure, or lifetime PEC. In some examples, each memory component 112A to 112N can store respective configuration data that specifies the respective reliability grade and lifetime PEC and current PEC. In some examples, a memory or register can be associated with all of the memory components 112A to 112N and can store a table that maps different groups, bins or sets of the memory components 112A to 112N to respective reliability grades, lifetime PEC values, and/or current PEC values.

In some examples, the memory sub-system 110 is a storage system. A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and a non-volatile dual in-line memory module (NVDIMM).

The computing environment 100 can include a host system 120 that is coupled to a memory system. The memory system can include one or more memory sub-systems 110. In some examples, the host system 120 is coupled to different types of memory sub-system 110. FIG. 1 illustrates one example of a host system 120 coupled to one memory sub-system 110. The host system 120 uses the memory sub-system 110, for example, to write data to the memory sub-system 110 and read data from the memory sub-system 110. As used herein, “coupled to” generally refers to a connection between components, which can be an indirect communicative connection or direct communicative connection (e.g., without intervening components), whether wired or wireless, including connections such as electrical, optical, magnetic, etc.

The host system 120 can be a computing device such as a desktop computer, laptop computer, network server, mobile device, embedded computer (e.g., one included in a vehicle, industrial equipment, or a networked commercial device), or such computing device that includes a memory and a processing device. The host system 120 can include or be coupled to the memory sub-system 110 so that the host system 120 can read data from or write data to the memory sub-system 110. The host system 120 can be coupled to the memory sub-system 110 via a physical host interface. Examples of a physical host interface include, but are not limited to, a serial advanced technology attachment (SATA) interface, a peripheral component interconnect express (PCIe) interface, a compute express link (CXL), a universal serial bus (USB) interface, a Fibre Channel interface, a Serial Attached SCSI (SAS) interface, etc. The physical host interface can be used to transmit data between the host system 120 and the memory sub-system 110. The host system 120 can further utilize an NVM Express (NVMe) interface to access the memory components 112A to 112N when the memory sub-system 110 is coupled with the host system 120 by the PCIe or CXL interface. The physical host interface can provide an interface for passing control, address, data, and other signals between the memory sub-system 110 and the host system 120.

The memory components 112A to 112N can include any combination of the different types of non-volatile memory components and/or volatile memory components. An example of non-volatile memory components includes a negative-and (NAND)-type flash memory and/or a 3D NAND flash memory. Each of the memory components 112A to 112N can include one or more arrays of memory cells such as single-level cells (SLCs) or multi-level cells (MLCs) (e.g., TLCs or QLCs). In some examples, a particular memory component 112 can include both an SLC portion and an MLC portion of memory cells. Each of the memory cells can store one or more bits of data (e.g., blocks) used by the host system 120. Although non-volatile memory components such as NAND-type flash memory are described, the memory components 112A to 112N can be based on any other type of memory, such as a volatile memory. In some examples, the memory components 112A to 112N can be, but are not limited to, random access memory (RAM), read-only memory (ROM), dynamic random access memory (DRAM), synchronous dynamic random access memory (SDRAM), phase change memory (PCM), magnetoresistive random access memory (MRAM), negative-or (NOR) flash memory, electrically erasable programmable read-only memory (EEPROM), and a cross-point array of non-volatile memory cells.

A cross-point array of non-volatile memory cells can perform bit storage based on a change of bulk resistance, in conjunction with a stackable cross-gridded data access array. Additionally, in contrast to many flash-based memories, cross-point non-volatile memory can perform a write-in-place operation, where a non-volatile memory cell can be programmed without the non-volatile memory cell being previously erased. Furthermore, the memory cells of the memory components 112A to 112N can be grouped as memory pages or blocks that can refer to a unit of the memory component 112 used to store data. For example, a single first row that spans a first set of the pages or blocks of the memory components 112A to 112N can correspond to or be grouped as a first block stripe and a single second row that spans a second set of the pages or blocks of the memory components 112A to 112N can correspond to or be grouped as a second block stripe.

The memory sub-system controller 115 can communicate with the memory components 112A to 112N to perform memory operations such as reading data, writing data, or erasing data at the memory components 112A to 112N and other such operations. The memory sub-system controller 115 can communicate with the memory components 112A to 112N to perform various memory management operations, such as different scan rates, different scan frequencies, different wear leveling, different read disturb management, garbage collection operations, different near miss ECC operations, first page read scan, and/or different dynamic data refresh.

The memory sub-system controller 115 can include hardware such as one or more integrated circuits and/or discrete components, a buffer memory, or a combination thereof. The memory sub-system controller 115 can be a microcontroller, special-purpose logic circuitry (e.g., a field programmable gate array (FPGA), an application specific integrated circuit (ASIC), etc.), or another suitable processor. The memory sub-system controller 115 can include a processor (processing device) 117 configured to execute instructions stored in local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120. In some embodiments, the local memory 119 can include memory registers storing memory pointers, fetched data, and so forth. The local memory 119 can also include read-only memory (ROM) for storing microcode. While the example memory sub-system 110 in FIG. 1 has been illustrated as including the memory sub-system controller 115, in another example of the present disclosure, a memory sub-system 110 may not include a memory sub-system controller 115, and can instead rely upon external control (e.g., provided by an external host, or by a processor 117 or controller separate from the memory sub-system 110).

In general, the memory sub-system controller 115 can receive commands or operations from the host system 120 and can convert the commands or operations into instructions or appropriate commands to achieve the desired access to the memory components 112A to 112N. In some examples, the commands or operations received from the host system 120 can specify configuration data for the memory components 112N to 112N. The configuration data can describe the lifetime PEC values and/or reliability grades associated with different groups of the memory components 112N to 112N and/or different WLs, WLGs, and/or blocks within each of the memory components 112N to 112N.

The memory sub-system controller 115 can be responsible for other memory management operations, such as wear leveling operations, garbage collection operations, error detection and error-correcting code (ECC) operations, encryption operations, caching operations, first page read scan operations, and address translations. The memory sub-system controller 115 can further include host interface circuitry to communicate with the host system 120 via the physical host interface. The host interface circuitry can convert the commands received from the host system 120 into command instructions to access the memory components 112A to 112N as well as convert responses associated with the memory components 112A to 112N into information for the host system 120.

The memory sub-system 110 can also include additional circuitry or components that are not illustrated. In some examples, the memory sub-system 110 can include a cache or buffer (e.g., DRAM or other temporary storage location or device) and address circuitry (e.g., a row decoder and a column decoder) that can receive an address from the memory sub-system controller 115 and decode the address to access the memory components 112A to 112N.

The memory devices can be raw memory devices (e.g., NAND), which are managed externally, for example, by an external controller (e.g., memory sub-system controller 115). The memory devices can be managed memory devices (e.g., managed NAND), which is a raw memory device combined with a local embedded controller (e.g., local media controllers) for memory management within the same memory device package. Any one of the memory components 112A to 112N can include a media controller (e.g., media controller 113A and media controller 113N) to manage the memory cells of the memory component (e.g., to perform one or more memory management operations), to communicate with the memory sub-system controller 115, and to execute memory requests (e.g., read or write) received from the memory sub-system controller 115.

The memory sub-system controller 115 can include a media operations manager 122. The media operations manager 122 can be configured to receive a request to read a WLG of a set of memory components. The media operations manager 122 stores a table that associates a first read level offset with a first region of the WLG and a second read level offset with a second region of the WLG. The media operations manager 122 reads a first set of data stored in the first region of the WLG using the first read level offset stored in the table and reads a second set of data stored in the second region of the WLG using the second read level offset stored in the table.

In some examples, the media operations manager 122 can comprise logic (e.g., a set of transitory or non-transitory machine instructions, such as firmware) or one or more components that causes the media operations manager 122 to perform operations described herein. The media operations manager 122 can comprise a tangible or non-tangible unit capable of performing operations described herein. Further details with regards to the operations of the media operations manager 122 are described below.

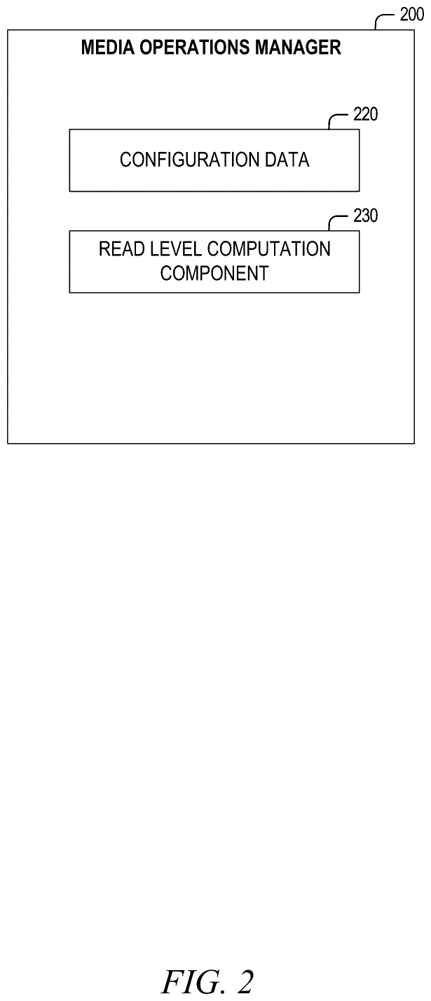

FIG. 2 is a block diagram of an example media operations manager 200 (corresponding to media operations manager 122), in accordance with some examples. As illustrated, the media operations manager 200 includes configuration data 220 and a read level computation component 230. For some cases, the media operations manager 200 can differ in components or arrangement (e.g., less or more components) from what is illustrated in FIG. 2.

The configuration data 220 accesses and/or stores configuration data associated with the memory components 112A to 112N. In some examples, the configuration data 220 is programmed into the media operations manager 200. For example, the media operations manager 200 can communicate with the memory components 112A to 112N to obtain the configuration data and store the configuration data 220 locally on the media operations manager 122. In some examples, the media operations manager 122 communicates with the host system 120. The host system 120 receives input from an operator or user that specifies parameters including lifetime PEC values of different WLs, WLGs, bins, groups, blocks, block stripes, memory dies, WLG threshold, WL threshold, maximum number of regions threshold, and/or sets of the memory components 112A to 112N. The media operations manager 122 receives configuration data from the host system 120 and stores the configuration data in the configuration data 220.

The configuration data 220 can store parameters for controlling when course and fine read level adjustments and/or computations are performed. As referred to herein, course and fine read level adjustments and/or computations utilize a valley track process to compute course and fine read level offsets, such as using combination of coarse (Digital CFByte) and fine (pARC). For example, the configuration data 220 can store a WLG threshold that is used to compare with a flow trigger rate for a WLG or one or more regions of a WLG defined by two or more WLs to control whether the WLG is divided into additional regions for performing coarse and fine read level offset computations. As another example, the configuration data 220 can store a WL threshold that is used to compare with a flow trigger rate for a WL of a WLG to control whether a particular WL or set of WLs are selected to be used to divide the WLG into additional regions. The configuration data 220 can store a maximum number of regions threshold to compare with a current quantity of regions of the WLG. This can be used to control whether to continue using prestored read level offsets to read data from a corresponding region of the WLG or to compute coarse and fine read level offsets for all subsequent reads to the WLG.

The read level computation component 230 can be used to selectively perform coarse and fine read level offset computations for reading data from a region of a WLG and/or each WL of a WLG. For example, the read level computation component 230 can store a table that associates an entire WLG and/or regions of the WLG with respective previously computed read level offsets. The read level computation component 230 can receive a request to read data from the WLG. The read level computation component 230 can determine which WL or set of WLs of the WLG are being read. The read level computation component 230 can access the table to identify a read level offset associated with the WL or set of WLs being read. Then, the read level computation component 230 can read the data from the WL or set of WLs using the read level offset retrieved from the table. The read level computation component 230 can then determine an additional set of WLs to be read from the WLG. The read level computation component 230 can then access the table to identify a read level offset associated with the additional set of WLs. Then, the read level computation component 230 can read the data from the additional set of WLs using the read level offset retrieved from the table. In some cases, these operations are performed when reading data from a WLG of the QLC block.

In some cases, the read level computation component 230 can generate a trigger rate or monitor and compute the recovery flow trigger rate for each WL being read and for the WLG and/or regions of the WLG. The term “recovery flow trigger rate” refers to the frequency at which recovery mechanisms are initiated to correct errors during data read operations. NAND flash memory, particularly as it scales to higher densities like those seen in QLC (Quad-Level Cell) technologies, is prone to various types of errors such as charge loss, read disturb, and cell-to-cell interference. These errors can lead to incorrect reading of the stored data, which can compromise data integrity. The recovery flow in NAND flash can involve error correction code (ECC) algorithms and other corrective actions designed to detect and correct these errors. The trigger rate for these recovery flows is a parameter as it indicates how often the memory sub-system controller 115 intervenes to correct data being read from the set of memory components 112A to 112N. A high recovery flow trigger rate can suggest that the set of memory components 112A to 112N is experiencing a high level of errors that may need correction, which can impact the overall performance and reliability of the memory sub-system 110.

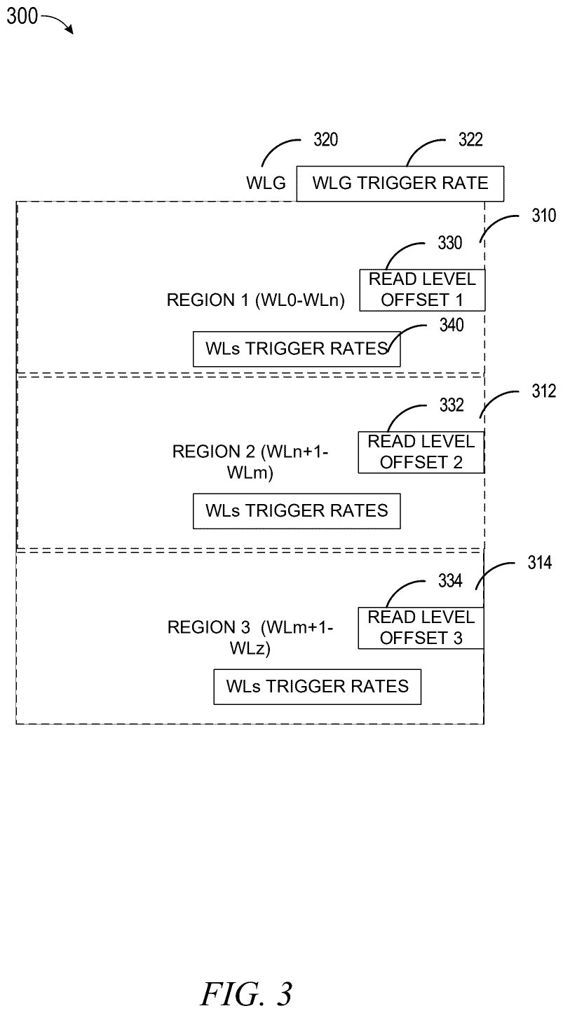

For example, as shown in the diagram 300 of FIG. 3, a QLC block can be generated to include one or more WLGs 320. As data is read from different WLs and/or regions of the WLG 320, the read level computation component 230 determines how often a recovery flow is performed. Based on this determination, the read level computation component 230 can update and/or store a WLG trigger rate 322. The WLG 320 can be divided into multiple regions, such as a first region 310, a second region 312, and a third region 314. Initially, the WLG 320 is divided using only one WL. Then, during subsequent reads or recovery flow triggers, the WLG 320 is further divided into additional regions using one or more additional WLs. These regions can be generated by the read level computation component 230 as data is being read using precomputed read level offsets and based on whether a recovery flow trigger rate reaches the WLG threshold. The first region 310 (e.g., the initial region) can be defined by a first set of WLs, such as WL0-WLn, the second region 312 can be defined by a second set of WLs, such as WLn+1-WLm, and the third region 314 can be defined by a third set of WLs, such as WLm+1-WLz. Each of the first region 310, second region 312, and third region 314 can be associated with a respective read level offset that has been precomputed using coarse and fine read level offset computations.

For example, the first region 310 can be associated with a first read level offset 330, the second region 312 can be associated with a second read level offset 332, and the third region 314 can be associated with a third read level offset 334. In this way, when the read level computation component 230 reads data from one or more WLs that are in the first region 310, the read level computation component 230 can use the first read level offset 330 to read the data to avoid having to recalibrate and recompute the coarse and fine read level offsets. Similarly, when the read level computation component 230 reads data from one or more WLs that are in the second region 312, the read level computation component 230 can use the second read level offset 332 to read the data to avoid having to recalibrate and recompute the coarse and fine read level offsets. While reading data from one or more of the regions of the WLG 320, the read level computation component 230 can determine the recovery flow trigger rate and update the respective WLs trigger rates 340 stored in association with each WLG region. For example, a first WLs trigger rate value can be maintained in association with the first region 310, a second WLs trigger rate value can be maintained in association with the second region 312, and/or a third WLs trigger rate value can be maintained in association with the third region 314.

In some examples, the read level computation component 230 determines that a QLC block has been programmed or written with one or more WLGs. In response, the read level computation component 230 initiates a process for precomputing and pre-associating coarse and fine read level offsets with the one or more WLGs and/or different regions of the WLGs. Initially, only one region exists in the WLG and the entire WLG is associated with a same coarse and fine read level offset. For example, the read level computation component 230 can initially select only one WL in a WLG and later can select additional one or more WLs from the WLG based on that initially selected one WL. The read level computation component 230 performs coarse and fine read level offset computations and reads the data from the selected one WL or the one or more WLs using the coarse and fine read level offset computations. The coarse and fine read level offset computations are then stored in a table in association with the WLG. In some cases, multiple coarse and fine read level offset computations are performed for different WLs in the WLG. The WLs can be randomly selected and/or selected based on information stored in the configuration data 220 that identifies WLs in the WLG that have reliability values that fail to transgress a reliability threshold. The read level computation component 230 can compute a mean or median of the multiple coarse and fine read level offset computations and can store that mean or median in association with the WLG.

The read level computation component 230 can continue reading data from the WLG using the coarse and fine read level offset computations associated with the WLG. While the data continues to be read, the read level computation component 230 can monitor the recovery flow trigger rate for each WL and the WLG. The read level computation component 230 can determine whether the recovery flow trigger rate for the WLG transgresses a WLG threshold. In response to determining that the recovery flow trigger rate for the WLG transgresses the WLG threshold, the read level computation component 230 can perform a process for dividing the WLG or region of the WLG into one or more additional regions.

Specifically, the read level computation component 230 can sample certain WLs in the WLG or region of the WLG for which the recovery flow trigger rate transgressed the WLG threshold. The read level computation component 230 can select which WLs to sample based on known reliability values that fail to transgress a reliability threshold and/or by randomly selecting WLs. The read level computation component 230 can read data from the selected WLs and monitor the RBER of the data read from the selected WLs. The read level computation component 230 can compare the RBER of each WLs and identify an individual WL having a highest RBER value than all other WLs in the group of WLs that was selected. The read level computation component 230 can use the individual WL that has been identified to divide the WLG into one or more regions. For example, a region of the WLG can be defined by a particular WL that corresponds to a beginning of the WLG or the beginning of a region of the WLG up to the individual WL that has been identified.

The read level computation component 230 can obtain the recovery trigger rate for each of the selected WLs or another group of WLs in the WLG or region of the WLG. The read level computation component 230 can compare that recovery trigger rate for the selected WLs. Any WL having a corresponding recovery trigger rate that transgresses the WL threshold, can be selected to create additional regions of the WLG.

The read level computation component 230 can then determine how many regions have been created in the WLG. The read level computation component 230 can compare the number of regions of the WLG to a maximum number of regions threshold. In response to determining that the number of regions of the WLG fails to transgress the maximum number of regions threshold, the read level computation component 230 can perform subsequent reads to the different regions of the WLG according to precomputed coarse and fine read level offsets. For example, as discussed above, the read level computation component 230 can initially select a certain set of WLs from a particular region of the WLG that was formed. The read level computation component 230 can perform coarse and fine read level offset computations for the certain set of WLs and can associate that coarse and fine read level offset with the particular region. The read level computation component 230 can perform subsequent reads to WLs in the particular region using the coarse and fine read level offset that have been precomputed until the recovery flow trigger rate for the particular region transgresses a WLG threshold. At that point, the particular region can be further divided in the manner discussed above based on the RBER of some WLs in the region and/or based on a recovery flow trigger rate of some WLs in the region. In response to determining that the number of regions of the WLG transgresses the maximum number of regions threshold, the read level computation component 230 can perform coarse and fine read level offsets for each subsequent read to any WL in the WLG.

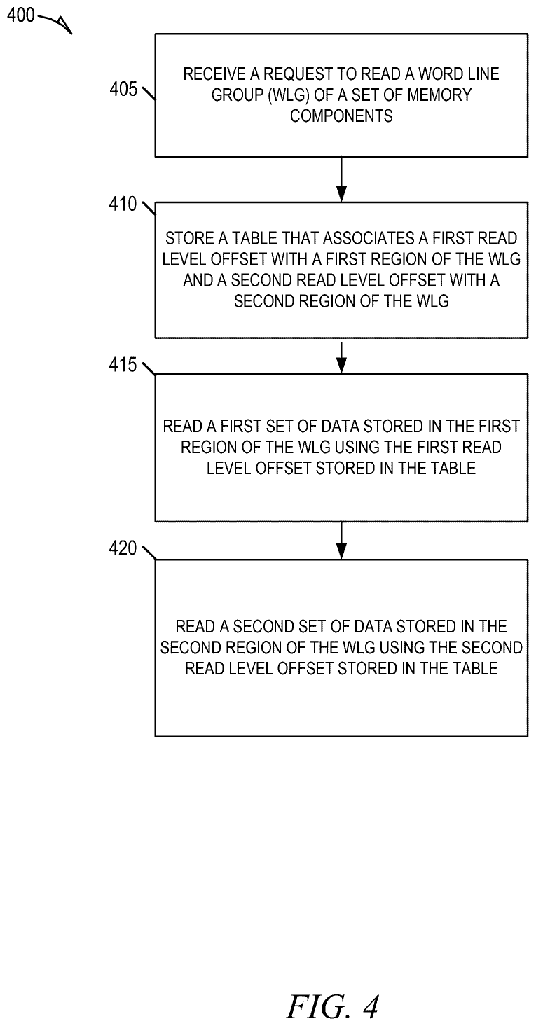

FIG. 4 is a flow diagram of an example method 400 to selectively perform coarse and fine read level offset computations, in accordance with some examples. The method 400 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some examples, the method 400 is performed by the media operations manager 122 of FIG. 1. Although the processes are shown in a particular sequence or order, unless otherwise specified, the order of the processes can be modified. Thus, the illustrated examples should be understood only as examples, and the illustrated processes can be performed in a different order, and some processes can be performed in parallel. Additionally, one or more processes can be omitted in various examples. Thus, not all processes are required in every example. Other process flows are possible.

Referring now to FIG. 4, the method (or process) 400 begins at operation 405, with a media operations manager 122 of a memory sub-system (e.g., memory sub-system 110) receives a request to read a word line group (WLG) of a set of memory components. At operation 410, the media operations manager 122 stores a table that associates a first read level offset with a first region of the WLG and a second read level offset with a second region of the WLG. Then, at operation 415, the media operations manager 122 reads a first set of data stored in the first region of the WLG using the first read level offset stored in the table and, at operation 420, reads a second set of data stored in the second region of the WLG using the second read level offset stored in the table.

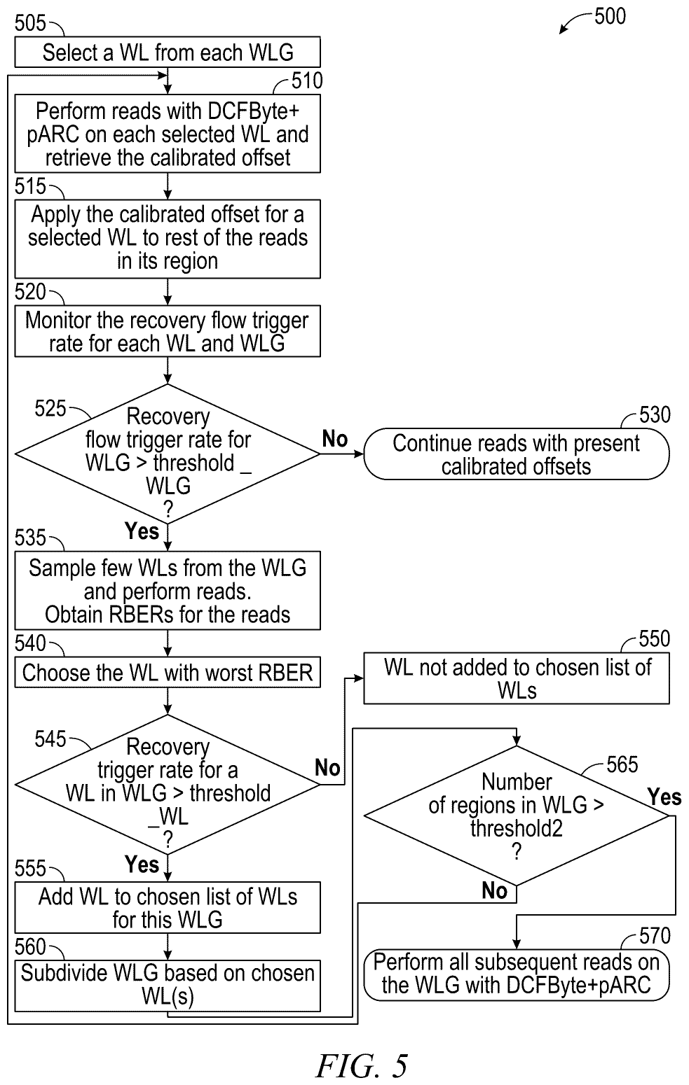

FIG. 5 is a flow diagram of an example method 500 to selectively perform coarse and fine read level offset computations, in accordance with some examples. The method 500 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some examples, the method 500 is performed by the media operations manager 122 of FIG. 1. Although the processes are shown in a particular sequence or order, unless otherwise specified, the order of the processes can be modified. Thus, the illustrated examples should be understood only as examples, and the illustrated processes can be performed in a different order, and some processes can be performed in parallel. Additionally, one or more processes can be omitted in various examples. Thus, not all processes are required in every example. Other process flows are possible.

Referring now to FIG. 5, the method (or process) 500 begins at operation 505, with a media operations manager 122 of a memory sub-system (e.g., memory sub-system 110) where only one WL is selected for each WLG initially. When the WLG gets divided into regions, one WL can be used as representative for each region and one or more additional WL(s) can be selected from each WLG of a QLC block that has been stored and/or from a particular region of the WLG (if the WLG has been previously divided into regions). Then, at operation 510, the media operations manager 122 performs reads on the selected WL(s) using newly computed coarse and fine read level offsets (e.g., calibrated offsets). The media operations manager 122 stores the calibrated offset in association with the region in which the selected WL(s) fall into and/or in association with the entire WLG. The media operations manager 122 applies the calibrated offset for the selected WL to reading data from other WLs in the same region and/or in the entire WLG at operation 515 (if no regions have yet been defined).

At operation 520, the media operations manager 122 monitors the recovery flow trigger rate for each WL and for the WLG (or region of the WLG) and the media operations manager 122 compares the recovery flow trigger rate for the WLG or region of the WLG to a WLG threshold at operation 525. If the recovery flow trigger rate fails to transgress the WLG threshold, the media operations manager 122 continues performing reads on the WLG or region of the WLG using the previously computed calibrated offsets at operation 530. Otherwise, the media operations manager 122 performs a process for generating or dividing the WLG or region of the WLG into additional regions. For example, the media operations manager 122 performs operation 535 where some WLs are sampled from the WLG or region of the WLG and reads are performed on the WLs. RBER values are obtained or computed based on reading the data and, at operation 540, a WL is selected in response to determining that the WL has a greater RBER value than all other WLs that were sampled. At operation 545, a recovery trigger rate for one or more WLs in the WLG and/or the region of the WLG is obtained and compared with the WL threshold. If the recovery trigger rate transgresses the WL threshold, the corresponding WL is selected for dividing the WLG or region of the WLG into additional regions at operation 555 (in additional to or alternative to the WL that was selected based on having the highest RBER value than the other sampled WLs). If the recovery trigger rate fails to transgress the WL threshold, no additional WLs are added to the selected list of WLs used to divide the WLG or region of the WLG into additional regions at operation 550.

At operation 560, the WLG is divided based on the selected WLs and, at operation 565, the media operations manager 122 determines how many regions currently exist in the entire WLG. In response to determining that the number of regions falls below a maximum number of regions threshold, the media operations manager 122 performs operation 510 where data is read from the newly formed regions using newly computed coarse and fine read level offsets. In response to determining that the number of regions transgresses the maximum number of regions threshold, the media operations manager 122 performs operation 570 where all subsequent reads to the WLG are performed using coarse and fine read level offset computations and without accessing previously computed offsets stored in a table.

In view of the disclosure above, various examples are set forth below. It should be noted that one or more features of an example, taken in isolation or combination, should be considered within the disclosure of this application.

Example 1: A system comprising: a set of memory components of a memory sub-system; and at least one processing device operatively coupled to the set of memory components, the at least one processing device being configured to perform operations comprising: receiving a request to read a word line group (WLG) of the set of memory components; storing a table that associates a first read level offset with a first region of the WLG and a second read level offset with a second region of the WLG; reading a first set of data stored in the first region of the WLG using the first read level offset stored in the table; and reading a second set of data stored in the second region of the WLG using the second read level offset stored in the table.

Example 2. The system of Example 1, wherein the memory sub-system comprises a three-dimensional (3D) NAND memory.

Example 3. The system of any one of Examples 1-2, wherein the first set of data and the second set of data are read from the set of memory components without computing coarse and fine read level offsets using a valley track process.

Example 4. The system of any one of Examples 1-3, the operations comprising: determining that a quantity of regions in the WLG transgresses a maximum number of regions; and in response to determining that the quantity of regions in the WLG transgresses the maximum number of regions, reading data stored in the WLG using coarse and fine read level offsets computed using a valley track process.

Example 5. The system of any one of Examples 1-4, the operations comprising: detecting that a quad level cell (QLC) block has been written; in response to detecting that the QLC block has been written, selecting a set of word lines (WLs); and performing a set of read operations on the selected set of WLs using coarse and fine read level offsets computed using a valley track process.

Example 6. The system of Example 5, wherein the set of WLs are selected randomly.

Example 7. The system of any one of Examples 5-6, wherein the set of WLs that are selected correspond to WLs having reliability values that fail to transgress a reliability threshold.

Example 8. The system of any one of Examples 5-7, the operations comprising: performing the set of read operations on all sub-blocks of the QLC block in the selected set of WLs.

Example 9. The system of any one of Examples 5-8, the operations comprising: performing the set of read operations on a portion of sub-blocks of the QLC block in the selected set of WLs that are associated with reliability values that fail to transgress a reliability threshold.

Example 10. The system of Example 9, the operations comprising: computing a plurality of coarse and fine read level offsets for the portion of the sub-blocks; computing a mean offset based on the plurality of coarse and fine read level offsets; and storing the mean offset in the table in association with the selected set of WLs.

Example 11. The system of Example 10, the operations comprising: performing subsequent reads on the selected set of WLs using the mean offset stored in the table without computing coarse and fine read level offsets using the valley track process.

Example 12. The system of any one of Examples 10-11, the operations comprising: computing a read recovery flow trigger rate for each WL in the WLG.

Example 13. The system of Example 12, the operations comprising: determining that the read recovery flow trigger rate for the WLG transgresses a WLG threshold; in response to determining that the read recovery flow trigger rate for the WLG transgresses the WLG threshold, selecting a portion of WLs in the WLG; and performing read operations on the selected portion of WLs.

Example 14. The system of Example 13, the operations comprising: computing a read bit error rate (RBER) for the selected portion of WLs in response to performing the read operations; identifying an individual WL in the selected portion of WLs having a larger RBER than the RBER of other WLs in the selected portion of WLs; and dividing the WLG into a plurality of regions comprising the first and second regions based on the identified individual WL.

Example 15. The system of any one of Examples 13-14, the operations comprising: identifying an individual WL in the WLG for which the read recovery flow trigger rate transgresses a WL threshold; and dividing the WLG into a plurality of regions comprising the first and second regions based on the identified individual WL.

Example 16. The system of Example 15, wherein the WLG threshold and the WL threshold are computed based on a read throughput associated with the recovery flow trigger rate.

Example 17. The system of any one of Examples 15-16, the operations comprising: determining how many regions are in the WLG in response to dividing the WLG into the plurality of regions; and in response to determining that a quantity of regions in the WLG transgresses a threshold, performing subsequent reads on the WLG using the valley track process.

Example 18. The system of Example 17, the operations comprising: in response to determining that the quantity of regions in the WLG fails to transgress the threshold, performing subsequent reads on the WLG according to the read level offsets stored in the table.

Methods and computer-readable storage medium with instructions for performing any one of the above Examples.

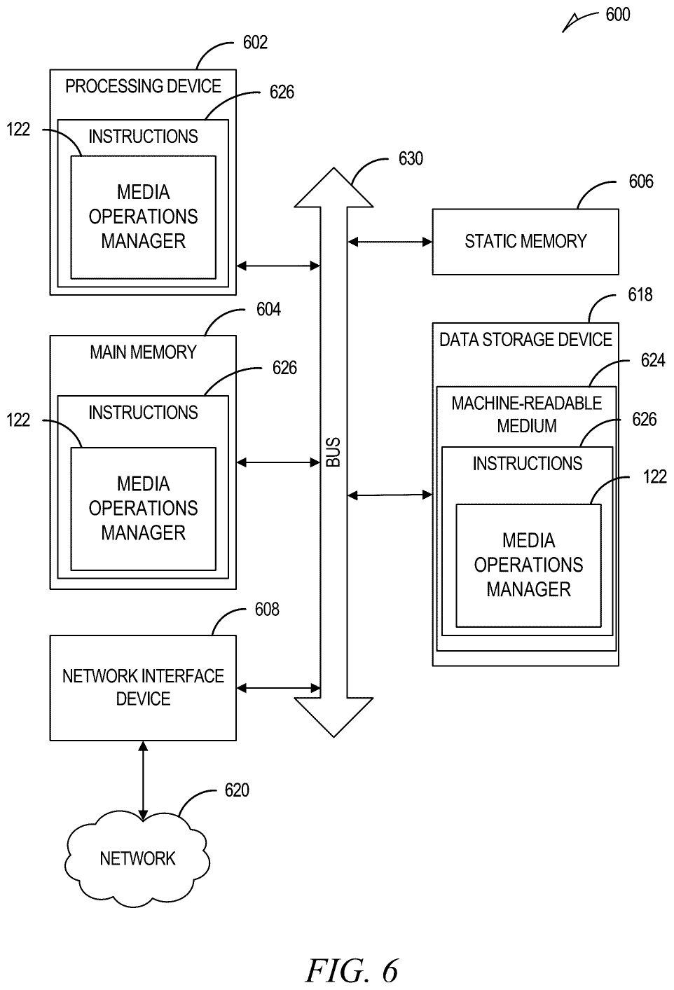

FIG. 6 illustrates an example machine in the form of a computer system 600 within which a set of instructions can be executed for causing the machine to perform any one or more of the methodologies discussed herein. In some embodiments, the computer system 600 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the media operations manager 122 of FIG. 1). In alternative embodiments, the machine can be connected (e.g., networked) to other machines in a local area network (LAN), an intranet, an extranet, and/or the Internet. The machine can operate in the capacity of a server or a client machine in a client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a network switch, a network bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a data storage device 618, which communicate with each other via a bus 630.

The processing device 602 represents one or more general-purpose processing devices such as a microprocessor, a central processing unit, or the like. More particularly, the processing device 602 can be a complex instruction set computing (CISC) microprocessor, a reduced instruction set computing (RISC) microprocessor, a very long instruction word (VLIW) microprocessor, a processor implementing other instruction sets, or processors implementing a combination of instruction sets. The processing device 602 can also be one or more special-purpose processing devices such as an application specific integrated circuit (ASIC), a field programmable gate array (FPGA), a digital signal processor (DSP), a network processor, or the like. The processing device 602 is configured to execute instructions 626 for performing the operations and steps discussed herein. The computer system 600 can further include a network interface device 608 to communicate over a network 620.

The data storage device 618 can include a machine-readable storage medium 624 (also known as a computer-readable medium) on which is stored one or more sets of instructions 626 or software embodying any one or more of the methodologies or functions described herein. The instructions 626 can also reside, completely or at least partially, within the main memory 604 and/or within the processing device 602 during execution thereof by the computer system 600, the main memory 604 and the processing device 602 also constituting machine-readable storage media. The machine-readable storage medium 624, data storage device 618, and/or main memory 604 can correspond to the memory sub-system 110 of FIG. 1.

In one embodiment, the instructions 626 implement functionality corresponding to the media operations manager 122 of FIG. 1. While the machine-readable storage medium 624 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system's memories or registers or other such information storage systems.

The present disclosure also relates to an apparatus for performing the operations herein. This apparatus can be specially constructed for the intended purposes, or it can include a general-purpose computer selectively activated or reconfigured by a computer program stored in the computer. Such a computer program can be stored in a computer-readable storage medium, such as, but not limited to, any type of disk including floppy disks, optical disks, CD-ROMs, and magnetic-optical disks; read-only memories (ROMs); random access memories (RAMs); erasable programmable read-only memories (EPROMs); EEPROMs; magnetic or optical cards; or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description above. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine-readable (e.g., computer-readable) storage medium such as a read-only memory (ROM), random access memory (RAM), magnetic disk storage media, optical storage media, flash memory components, and so forth.

In the foregoing specification, embodiments of the disclosure have been described with reference to specific example embodiments thereof. It will be evident that various modifications can be made thereto without departing from the broader scope of the disclosure as set forth in the following claims. The specification and drawings are, accordingly, to be regarded in an illustrative sense rather than a restrictive sense.

What is claimed is:

1. A system comprising:
a set of memory components of a memory sub-system; and
at least one processing device operatively coupled to the set of memory components, the at least one processing device being configured to perform operations comprising:
receiving a request to read a word line group (WLG) of the set of memory components;
storing a table that associates a first read level offset with a first region of the WLG and a second read level offset with a second region of the WLG;
reading a first set of data stored in the first region of the WLG using the first read level offset stored in the table; and
reading a second set of data stored in the second region of the WLG using the second read level offset stored in the table.

2. The system of claim 1, wherein the memory sub-system comprises a three-dimensional (3D) NAND memory.

3. The system of claim 1, wherein the first set of data and the second set of data are read from the set of memory components without computing coarse and fine read level offsets using a valley track process.

4. The system of claim 1, the operations comprising:
determining that a quantity of regions in the WLG transgresses a maximum number of regions; and
in response to determining that the quantity of regions in the WLG transgresses the maximum number of regions, reading data stored in the WLG using coarse and fine read level offsets computed using a valley track process.

5. The system of claim 1, the operations comprising:
detecting that a quad level cell (QLC) block has been written;
in response to detecting that the QLC block has been written, selecting a set of word lines (WLs); and
performing a set of read operations on the selected set of WLs using coarse and fine read level offsets computed using a valley track process.

6. The system of claim 5, wherein the set of WLs are selected randomly.

7. The system of claim 5, wherein the set of WLs that are selected correspond to WLs having reliability values that fail to transgress a reliability threshold.

8. The system of claim 5, the operations comprising:
performing the set of read operations on all sub-blocks of the QLC block in the selected set of WLs.

9. The system of claim 5, the operations comprising:
performing the set of read operations on a portion of sub-blocks of the QLC block in the selected set of WLs that are associated with reliability values that fail to transgress a reliability threshold.

10. The system of claim 9, the operations comprising:
computing a plurality of coarse and fine read level offsets for the portion of the sub-blocks;
computing a mean offset based on the plurality of coarse and fine read level offsets; and
storing the mean offset in the table in association with the selected set of WLs.

11. The system of claim 10, the operations comprising:
performing subsequent reads on the selected set of WLs using the mean offset stored in the table without computing coarse and fine read level offsets using the valley track process.

12. The system of claim 10, the operations comprising:
computing a read recovery flow trigger rate for each WL in the WLG.

13. The system of claim 12, the operations comprising:
determining that the read recovery flow trigger rate for the WLG transgresses a WLG threshold;
in response to determining that the read recovery flow trigger rate for the WLG transgresses the WLG threshold, selecting a portion of WLs in the WLG; and
performing read operations on the selected portion of WLs.

14. The system of claim 13, the operations comprising:
computing a read bit error rate (RBER) for the selected portion of WLs in response to performing the read operations;
identifying an individual WL in the selected portion of WLs having a larger RBER than the RBER of other WLs in the selected portion of WLs; and
dividing the WLG into a plurality of regions comprising the first and second regions based on the identified individual WL.

15. The system of claim 13, the operations comprising:
identifying an individual WL in the WLG for which the read recovery flow trigger rate transgresses a WL threshold; and
dividing the WLG into a plurality of regions comprising the first and second regions based on the identified individual WL.

16. The system of claim 15, wherein the WLG threshold and the WL threshold are computed based on a read throughput associated with the recovery flow trigger rate.

17. The system of claim 15, the operations comprising:
determining how many regions are in the WLG in response to dividing the WLG into the plurality of regions; and
in response to determining that a quantity of regions in the WLG transgresses a threshold, performing subsequent reads on the WLG using the valley track process.

18. The system of claim 17, the operations comprising:
in response to determining that the quantity of regions in the WLG fails to transgress the threshold, performing subsequent reads on the WLG according to the read level offsets stored in the table.

19. A method comprising:
receiving a request to read a word line group (WLG) of a set of memory components;
storing a table that associates a first read level offset with a first region of the WLG and a second read level offset with a second region of the WLG;
reading a first set of data stored in the first region of the WLG using the first read level offset stored in the table; and
reading a second set of data stored in the second region of the WLG using the second read level offset stored in the table.

20. A non-transitory computer-readable storage medium comprising instructions that, when executed by at least one processing device, cause the at least one processing device to perform operations comprising:
receiving a request to read a word line group (WLG) of a set of memory components;
storing a table that associates a first read level offset with a first region of the WLG and a second read level offset with a second region of the WLG;
reading a first set of data stored in the first region of the WLG using the first read level offset stored in the table; and
reading a second set of data stored in the second region of the WLG using the second read level offset stored in the table.
